(19) United States
(12) Patent Application Publication
(10) Pub. No.: US 2017/0186904 A1
(43) Pub. Date: Jun. 29, 2017

(54) STACK-LIKE MULTI-JUNCTION SOLAR CELL

(71) Applicant: AZUR SPACE Solar Power GmbH, Heilbronn (DE)

(72) Inventors: Wolfgang GUTER, Stuttgart (DE); Matthias MEUSEL, Heilbronn (DE); Tobias ROESENER, Muenchen (DE)

(73) Assignee: AZUR SPACE Solar Power GmbH, Heilbronn (DE)

(21) Appl. No.: 15/390,170

(22) Filed: Dec. 23, 2016

(30) Foreign Application Priority Data
Dec. 25, 2015 (DE) 10 2015 016 822.3

(51) Int. Cl. H01L 31/0687; H01L 31/0304; H01L 31/054; H01L 31/0693

(52) U.S. Cl. CPC H01L 31/06875; H01L 31/0693; H01L 31/03046; H01L 31/03042; H01L 31/0547

(57) ABSTRACT

A multi-junction solar cell having at least three partial cells having an emitter and a base. The first partial cell comprises a first layer of a compound containing at least the elements GaInP, and the energy band gap of the first layer is greater than 1.75 eV, and wherein the second partial cell has a second layer of a compound having at least the elements GaAs and the lattice constant of the second layer is in the range between 5.635 Å and 5.675 Å, and wherein the third partial cell has a third layer of a compound having at least the elements GaInAs and the energy band gap of the third layer is smaller than 1.25 eV and the lattice constant of the third layer is greater than 5.700 Å.

This nonprovisional application claims priority under 35 U.S.C. §119(a) to German Patent Application No. 10 2015 016 822.3, which was filed in Germany on Dec. 25, 2015, and which is herein incorporated by reference.

### BACKGROUND OF THE INVENTION

Field of the Invention

The invention relates to a stack-like multi-junction solar cell.

Description of the Background Art

An inverted metamorphic four-junction solar cell (IMM4J) with a beginning-of-life (BOL) efficiency of approx. 34% (AMO) and a relatively low end-of-life (EOL) residual factor of approx. 82% as compared to commercially available triple-junction solar cells is known from the publication “Experimental Results from Performance Improvement and Radiation Hardening of Inverted Metamorphic Multi-Junction Solar Cells” by Patel et al., Proceedings of 37th IEEE PVSC, Seattle (2011). The epitaxial deposition on the growth substrate is here inverted in comparison with the application and orientation of the solar cell to the sun.

Furthermore, from the publication “Development of Advanced Space Solar Cells at Spectrolab” by Boisvert et al., in Proc. of 35th IEEE PVSC, Honolulu, Hi., 2010, ISBN: 978-1-4244-5891-2, GaInP/GaAs/GaInAsP/GaInAs four-junction solar cells based on semiconductor bonding technology are known.

Another four-junction solar cell is also known from the publication “Wafer bonded four-junction GaInP/GaAs/GaInAsP/GaInAs concentrator solar cells with 44.7% efficiency” by Dimroth et al. in Progr. Photovolt: Res. Appl. 2014; 22: 277-282.

In the two last-mentioned two publications, GaInAsP solar cells with an energy band gap of approximately 1.0 eV are deposited in a lattice-matched manner, proceeding from an InP substrate. The upper solar cells with higher band gap are produced in a second deposition in inverted order on a GaAs substrate. The formation of the entire multi-junction solar cell takes place by means of a direct semiconductor bond of the two epitaxial wafers, with subsequent removal of the GaAs substrate and further process steps.

CN 103346191 A describes a four-junction solar cell grown on two opposite sides of a substrate.

However, using a bonding process as the manufacturing process is cost-intensive and reduces the yield during production.

The optimization of the radiation hardness, in particular also for very high radiation doses, is an important goal in the development of future spacecraft solar cells. The goal is to increase the end-of-life (EOL) efficiency as well as to increase the initial, or beginning-of-life (BOL), efficiency.

Furthermore, production costs are of decisive importance. The industrial standard at the time of the invention is given by the lattice-matched and metamorphic GaInP/GaInAs/Ge triple-function solar cells. For this purpose, multi-junction solar cells are produced by depositing the GaInP top and GaInAs center cells onto a substrate which is relatively inexpensive relative to InP substrates, wherein the Ge substrate forms the partial cell.

### SUMMARY OF THE INVENTION

It is therefore an object of the invention to further develop the state of the art.

According to an exemplary embodiment of the invention, a stack-like multi-junction solar cell is provided, comprising at least three partial cells, each of the three partial cells having an emitter and a base, and the first partial cell comprising a first layer of a compound with at least the elements GaInP, and the energy band gap of the first layer is greater than 1.75 eV, and the lattice constant of the first layer is in the range between 5.635 Å and 5.675 Å, and wherein the second partial cell has a second layer of a compound having at least the elements GaAs and the energy band gap of the second layer is in the range between 1.35 eV and 1.70 eV, and the lattice constant of the second layer is in the range between 5.635 Å and 5.675 Å, and wherein the third partial cell comprises a third layer of a compound with at least the elements GaInAs and the energy band gap of the third layer is less than 1.25 eV, and the lattice constant of the third layer is greater than 5.700 Å. The thickness of the three layers is in each case greater than 100 nm and the three layers are designed as part of the emitter and/or as part of the base and/or as part of the space charge zone of the corresponding three partial cells lying between the emitter and the base. A metamorphic buffer is formed between the second partial cell and the third partial cell, wherein the metamorphic buffer has a sequence of at least three layers and the lattice constants of the layers of the buffer are greater than the lattice constant of the second layer and the lattice constant of the layers of the buffer in the sequence increases in the direction towards the third partial cell from layer to layer. At least one of the two layers of the second partial cell, i.e., the second layer or of the third partial cell, i.e., the third layer, comprises a compound with at least the elements GaInAsP and has a phosphorus content of greater than 1% and an indium content of greater than 1%. No semiconductor bond is formed between two partial cells of the entire stack of the multi-junction solar cell.

It can be understood that the stack-like multi-junction solar cell is constructed in a monolithic manner. It is also noted that in each of the solar cells of the multi-junction solar cell, an absorption of photons and thus a generation of charge carriers takes place, wherein the sunlight is always irradiated first by the partial cell with the largest band gap. In other words, the uppermost partial cell of the solar cell stack first absorbs the short-wave portion of the light. In this case, the photons thus first pass through the first partial cell, subsequently through the second partial cell and then through the third partial cell. In an equivalent circuit diagram, the individual solar cells of the multi-junction solar cell are connected in series, i.e., the partial cell with the lowest current has a limiting effect.

It should also be noted that the terms emitter and base can denote either the p-doped or the n-doped layers in the respective partial cell.

The semiconductor layers can be deposited on a growth substrate by epitaxial methods such as, for example, MOVPE. The lattice constant regions indicated for the first partial cell and second partial cell, or for the first layer and the second layer, essentially correspond to the lattice constants of a GaAs substrate or a Ge substrate. In other words, the deposits of the layers of the individual partial cells can be described as at least roughly lattice-matched with respect to the substrates. In this case, an inverted sequence of the partial cells—a so-called IMM (inverted metamorphic) cell stack—is referred to during the manufacturing process, i.e. the cells with the higher band gap are prepared first.

Surprisingly, the partial cells deposited on GaAs or Ge substrates have a higher radiation hardness, provided that the partial cells formed at least predominantly or completely of a compound of GaInAsP as compared to partial cells formed of a compound of GaAs or GaInAs.

Until now, the use of a GaInAsP partial cell appeared to the skilled person to be disadvantageous, since the deposition of the quaternary GaInAsP is technically considerably more challenging as compared to GaAs or GaInAs, and the energy band gap of the partial cell also increases with the addition of phosphorus. Technically more challenging means, among other things, that the flows in the reactor must be controlled and adjusted by at least four sources.

Further studies have shown, however, that the increase in band gap can be compensated by phosphorus in the inverted metamorphic cell architecture by adaptation of the metamorphic buffer with regard to a higher indium content. A further possibility is to increase the energy band gap(s) of the partial cell(s) arranged under the GaInAsP partial cell(s)—e.g. by using GaInAsP also for these partial cells—by means of which a suitable band gap combination for the partial cells of the multi-junction solar cell can be found.

Surprisingly, depending on the precise design of the multi-junction solar cell, a slight lowering of the BOL efficiency can also be accepted by using GaInAsP partial cells, since a significant increase in the EOL efficiency due to the higher radiation stability of the GaInAsP partial cell(s) is achieved.

It can be understood that, in particular, the stated phosphorus content is based on the total content of the group V atoms. Correspondingly, the indium content given is based on the total content of the group III atoms. That is, in the case of the compound GaI—xInxAs1—YPY, the indium content is X and the phosphorus content is Y, and thus a Y-value of 0.5 is obtained for a phosphorus content of 50%.

The term “semiconductor bond” in particular includes that no direct semiconductor bond is formed between any two partial cells of the solar cell stack, that is, the solar cell stack is not produced from two partial stacks which have been deposited on different substrates and have subsequently been joined together via a semiconductor bond.

So-called heterojunction solar cells with an emitter formed of GaInP and a space charge zone and/or base formed of GaInAs are not regarded as a second and/or third partial cell with a layer of a compound with at least the elements GaInAsP. However, a heterojunction solar cell with an emitter formed of GaInP and a space charge zone and/or base formed of GaInAsP is regarded as a second and/or third partial cell with a layer of a compound with at least the elements GaInAsP.

In a further development, the lattice constant of the first layer and/or the lattice constant of the second layer is in a range between 5.640 Å and 5.670 Å.

In an embodiment, the lattice constant of the first layer and/or the lattice constant of the second layer is in a range between 5.645 Å and 5.665 Å.

In an embodiment, the lattice constant of the first layer differs from the lattice constant of the second layer by less than 0.2%. Preferably, the lattice constant of the third layer is greater than 5.730 Å.

In an embodiment, at least one of the two layers are formed of a compound with at least the elements GaInAsP and preferably has a phosphorus content of less than 35%.

In one embodiment, both layers have a thickness greater than 0.4 μm or greater than 0.8 μm.

In an embodiment, the two layers of the second partial cell or of the third partial cell are formed of a compound with at least the elements GaInAsP and have a phosphorus content of greater than 1% and an indium content of greater than 1%.

In a further development, a fourth partial cell is provided, wherein the fourth partial cell comprises a fourth layer of a compound with at least the elements GaInAs and the energy band gap of the fourth layer is at least 0.15 eV smaller than the energy band gap of the third layer and the thickness of the fourth layer is greater than 100 nm, and the fourth layer is formed as part of the emitter and/or as part of the base and/or as part of the space charge zone situated between emitter and base.

In another development, the fourth layer formed of a compound with at least the elements GaInAsP and has a phosphorus content greater than 1% and less than 35% and an indium content greater than 1%.

In an embodiment, a semiconductor mirror is formed between two partial cells and/or the semiconductor mirror is arranged under the lowest partial cell with the lowest energy band gap.

In a further development, the first layer of the first partial cell is formed of a compound with at least the elements AIGaInP. Preferably, the multi-junction solar cell does not have a Ge partial cell.

In an embodiment, a second metamorphic buffer is formed between the third partial cell and the fourth partial cell.

In an embodiment, the multi-junction solar cell has a fifth partial cell.

In a further development, the multi-junction solar cell has at least four partial cells, wherein the third layer formed of a compound with at least the elements GaInAsP and has a phosphorus content greater than 50%, and the multi-junction solar cell has exactly one metamorphic buffer and/or the lattice constants of the fourth layer differ by less than 0.3% from the lattice constants of the third layer.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1a is a cross section of an embodiment according to the invention as a triple-function solar cell in a first alternative,

FIG. 1b is a cross section of an embodiment according to the invention as a triple-function solar cell in a second alternative,

FIG. 1c is a cross section of an embodiment according to the invention as a triple-junction solar cell in a third alternative,

FIG. 2a is a cross section of an embodiment according to the invention as a four-junction solar cell in a first alternative,

FIG. 2b is a cross section of an embodiment according to the invention as a four-junction solar cell in a second alternative,

FIG. 2c is a cross section of an embodiment according to the invention as a four-junction solar cell in a third alternative, and

FIG. 2d is a cross section of an embodiment according to the invention as a four-junction solar cell in a fourth alternative.

### DETAILED DESCRIPTION

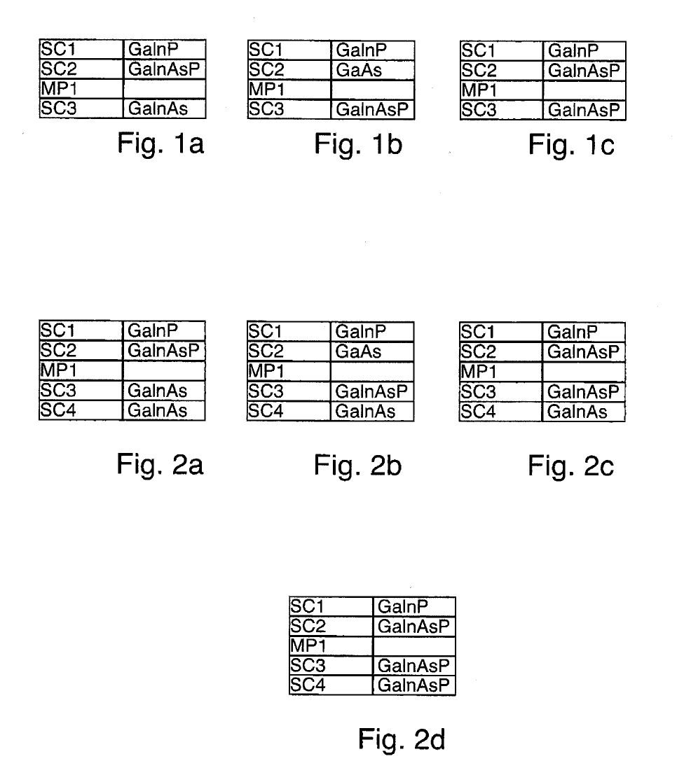

The illustration in FIG. 1a shows a cross section of an embodiment according to the invention of a stack-like monolithic multi-junction solar cell MS; in the following, the individual solar cells of the stack are referred to as a partial cell. The multi-junction solar cell MS has a first partial cell SC1, wherein the first partial cell SC1 formed of a GaInP compound and has the largest band gap of the entire stack above 1.75 eV. A second partial cell SC2, formed of a GaInAsP compound, is arranged underneath the first partial cell SC1. The second partial cell SC2 has a smaller band gap than the first partial cell SC1. Under the second partial cell SC2, a third partial cell SC3 formed of an InGaAs compound is arranged under the second partial cell SC2, wherein the third partial cell SC3 has the smallest band gap. In the present case, the third partial cell SC3 has an energy band gap of less than 1.25 eV.

A metamorphic buffer MP1 is formed between the second partial cell SC2 and the third partial cell SC3. The buffer MP1 is formed of a plurality of layers, wherein the lattice constant within the buffer MP1 generally decreases from layer to layer of the buffer MP1 in the direction of the third partial cell SC3. Introducing the buffer MP1 is advantageous if the lattice constant of the third partial cell SC3 does not match the lattice constant of the second partial cell SC2.

It is understood that a tunnel diode can be formed between the individual partial cells SC1, SC2 and SC3.

It is also understood that each of the three partial cells SC1, SC2 and SC3 each have an emitter and a base, wherein the thickness of the second partial cell SC2 is designed to be greater than 0.4 μm.

The lattice constant of the first partial cell SC1 and the lattice constant of the second partial cell SC2 are matched to one another or are the same. In other words, the partial cells SC1 and SC2 are “lattice-matched” to one another.

Since the band gap of the first partial cell SC1 is greater than the band gap of the second partial cell SC2, and the band gap of the second partial cell SC2 is greater than the band gap of the third partial cell SC3, solar irradiation takes place through the surface of the first partial cell SC1.

FIG. 1b shows a cross section of an embodiment according to the invention as a triple-junction solar cell in a second alternative. In the following, only the differences from the embodiment shown in conjunction with FIG. 1a are explained. Hereafter, the second partial cell SC2 formed of a GaAs compound and the third partial cell SC3 formed of a GaInAsP compound.

FIG. 1c shows a cross section of an embodiment according to the invention as a triple-junction solar cell in a third alternative. In the following, only the differences from the embodiment illustrated in conjunction with FIG. 1a are explained. Hereafter, the second partial cell SC2 and the third partial cell SC3 each formed of a GaInAsP compound.

FIG. 2a shows a cross section of an embodiment according to the invention as a four-junction solar cell in a first alternative. In the following, only the differences from the embodiment shown in conjunction with FIG. 1a are explained. Below the third partial cell SC3, a fourth partial cell SC4 is formed on a GaInAs compound. The lattice constant of the fourth partial cell SC4 and the third partial cell SC3 are matched with one another or are the same.

The fourth partial cell SC4 has a smaller band gap than the third partial cell SC3.

FIG. 2b shows a cross section on an embodiment according to the invention as a four-junction solar cell in a second alternative. In the following, only the differences from the preceding embodiments will be explained. The second partial cell SC2 formed of a GaAs compound and the third partial cell SC3 now formed of an InGaAsP compound.

FIG. 2c shows a cross section of an embodiment according to the invention as a four-junction solar cell in a third alternative. In the following, only the differences from the embodiment shown in FIG. 2a are explained. The third partial cell SC3 formed of a GaInAsP compound.

FIG. 2d shows a cross section of an embodiment according to the invention as a four-junction solar cell in a fourth alternative. In the following, only the differences from the embodiment shown in FIG. 2a are explained. The third partial cell SC3 and the fourth partial cell SC4 each formed of a GaInAsP compound.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A stack-like multi-junction solar cell comprising:
at least a first, second, and third partial cell, each of the first, second, and third partial cells having an emitter and a base; and
a metamorphic buffer formed between the second partial cell and the third partial cell, the metamorphic buffer having a sequence of at least three layers, and lattice elements of the buffer layers being greater than a lattice constant of the second layer, and the lattice constant of the buffer layers in the sequence increasing in a direction towards the third partial cell from layer to layer,
wherein the first partial cell comprises a first layer of a compound having at least the elements GaInP and an energy band gap of the first layer being greater than 1.75 eV, and the lattice constant of the first layer being in a range between 5.635 Å and 5.675 Å,
wherein the second partial cell comprises a second layer of a compound having at least the elements GaAs and an energy band gap of the second layer being in a range between 1.35 eV and 1.70 eV, and the lattice constant of the second layer being in the range between 5.635 Å and 5.675 Å,
wherein the third partial cell comprises a third layer of a compound having at least the elements GaInAs and an energy band gap of the third layer being less than 1.25 eV, and the lattice constant of the third layer being greater than 5,700 Å,
wherein a thickness of the three layers is greater than 100 nm and the three layers are designed as part of the emitter and/or as part of the base and/or as part of the space charge zone of the corresponding three partial cells situated between the emitter and base,
wherein at least the second layer and/or the third layer is formed of a compound with at least the elements GaInAsP and has a phosphorus content of greater than 1% and has an indium content of greater than 1%, and
wherein no semiconductor bond is formed between two partial cells of the stack.

2. The multi-junction solar cell according to claim 1, wherein the lattice constant of the first layer and/or the lattice constant of the second layer are in a range between 5.640 Å and 5.670 Å.

3. The multi-junction solar cell according to claim 1, wherein the lattice constant of the first layer and/or the lattice constant of the second layer lie in a range between 5.645 Å and 5.665 Å.

4. The multi-junction solar cell according to claim 1, wherein the lattice constant of the first layer differs from the lattice constant of the second layer by less than 0.2%.

5. The multi-junction solar cell according to claim 1, wherein the lattice constant of the third layer is greater than 5.730 Å.

6. The multi-junction solar cell according to claim 1, wherein at least the second layer and/or the third layer are formed of a compound with at least the elements GaInAsP and has a phosphorus content of less than 35%.

7. The multi-junction solar cell according to claim 1, wherein both layers have a thickness greater than 0.4 μm or greater than 0.8 μm.

8. The multi-junction solar cell according to claim 1, wherein the second layer and the third layer formed of a compound with at least the elements GaInAsP and have a phosphorus content of greater than 1% and an indium content of greater than 1%.

9. The multi-junction solar cell according to claim 1, wherein the multi-junction solar cell has a fourth partial cell, the fourth partial cell having a fourth layer of a compound with at least the elements GaInAs and an energy band gap of the fourth layer being at least 0.15 eV smaller than an energy band gap of the third layer, and the thickness of the fourth layer being greater than 100 nm, and the fourth layer being a part of the emitter and/or a part of the base and/or a part of the space charge zone between the emitter and the base.

10. The multi-junction solar cell according to claim 9, wherein the fourth layer is formed of a compound with at least the elements GaInAsP and has a phosphorus content greater than 1% and less than 35% and an indium content greater than 1%.

11. The multi-junction solar cell according to claim 1, wherein a semiconductor mirror is formed between two partial cells and/or the semiconductor mirror is arranged below the lowest partial cell with the lowest energy band gap.

12. The multi-junction solar cell according to claim 1, wherein the first layer of the first partial cell is formed of a compound with at least the elements AIGaInP.

13. The multi-junction solar cell according to claim 1, wherein the multi-junction solar cell has no Ge partial cell.

14. The multi-junction solar cell according to claim 1, wherein a second metamorphic buffer is formed between the third partial cell and the fourth partial cell.

15. The multi-junction solar cell according to claim 1, wherein a fifth partial cell is provided.

16. The multi-junction solar cell according to claim 1, wherein the multi-junction solar cell has at least four partial cells, wherein the third layer is formed a compound having at least the elements GaInAsP, and has a phosphorus content greater than 50%, and wherein the multi-junction solar cell has exactly one metamorphic buffer and/or lattice constants of the fourth layer differ from lattice constant of the third layer by less than 0.3%.

17. The multi-junction solar cell according to claim 1, wherein no substrate is arranged between the two partial cells.
